(19) United States
(12) Patent Application Publication
(10) Pub. No.: US 2024/0113033 A1
(43) Pub. Date: Apr. 4, 2024

(54) DYNAMIC RANDOM-ACCESS MEMORY IN A MOLDING BENEATH A DIE

(71) Applicant: Intel Corporation, Santa Clara, CA (US)

(72) Inventors: Eng Huat GOH, Ayer Itam (MY); Jiun Hann SIR, Gelugor (MY); Poh Boon KHOO, Perai (MY); Hazwani JAFFAR, Kepala Batas (MY); Hooi San LAM, Air Itam (MY)

(21) Appl. No.: 17/956,753

(22) Filed: Sep. 29, 2022

(51) Int. Cl. H01L 23/538; H01L 23/31; H01L 25/00; H01L 25/065; H01L 25/18

(52) U.S. Cl. CPC H01L 23/5389; H01L 23/3128; H01L 23/5383; H01L 23/5386; H01L 25/0652; H01L 25/18; H01L 25/50; H01L 2225/0651; H01L 2225/06517; H01L 2225/06562; H01L 2225/06572; H01L 2225/06586; H01L 2225/06589

(57) ABSTRACT

Embodiments herein relate to systems, apparatuses, or processes directed to a package that includes a die, which may be a processor die, coupled with a first side of a substrate and one or more dies, which may be one or more memory dies, that are coupled with a second side of the substrate opposite the first side of the substrate. All or part of the memory dies may be directly below the die with respect to a plane of the substrate and may be partially or completely within a molding. Other embodiments may be described and/or claimed.

### FIELD

Embodiments of the present disclosure generally relate to the field of package assemblies, and in particular package assemblies that include magnetic cores.

### BACKGROUND

Continued reduction in end-product size of mobile electronic devices, such as smart phones and ultrabooks, is a driving force for the development of reduced-sized packages. In addition, increasing the bandwidth between memory and processor modules will improve operational performance of these packages.

### BRIEF DESCRIPTION OF THE DRAWINGS

FIGS. 1A-1C illustrate cross section side views of legacy on package memory implementations.

FIG. 2 illustrates cross section side views of packages that include memory dies that are beneath a top die, in accordance with various embodiments.

FIG. 3 illustrates cross section side views of memory dies that are at least partially directly below a top die, in accordance with various embodiments.

FIG. 4 illustrates a top-down view of a package that includes multiple memory dies that are at least partially directly below a top die, in accordance with various embodiments.

FIGS. 5A-5I illustrate cross section side views of stages in a manufacturing process for creating a package with memory dies in a molding that are beneath a top die, with a capacitor proximate to the top die, in accordance with various embodiments.

FIGS. 6A-6I illustrate cross section side views of stages in a manufacturing process for creating a package with memory dies in a molding that are beneath the top die, with a capacitor at the edge of the package where the capacitor is electrically coupled with the top die using metal vias, in accordance with various embodiments.

FIG. 7 illustrates an example of a process for creating a package that includes one or more memory dies in a molding beneath a top die, in accordance with various embodiments.

FIG. 8 schematically illustrates a computing device, in accordance with embodiments.

### DETAILED DESCRIPTION

Embodiments of the present disclosure may generally relate to systems, apparatus, and/or processes directed to a package that includes a die, which may be referred to as a top die or a die complex, coupled with a first side of a substrate and with one or more dies, which may be one or more memory dies, that are coupled with a second side of the substrate opposite the first side of the substrate. In embodiments, the memory dies may include dynamic random access memory (DRAM) dies, static random access memory (SRAM) dies, or some other memory die.

In embodiments, the one or more memory dies are electrically coupled with the die through the substrate. In embodiments, the substrate may include one or more layers, such as, for example, buildup or redistribution layers, that include electrically conductive traces or routings that are used to electrically couple the one or more memory dies with the die. In embodiments, the one or more memory dies may be at least partially surrounded, or at least partially encapsulated, within a molding or a mold compound. Mold or molding compounds generally comprise epoxy resins, phenolic hardeners, silicas, and catalysts. In some embodiments, one or more redistribution layers (RDL) may be on a side of the molding and may be used to electrically couple the die or the substrate to another substrate such as a motherboard or a printed circuit board (PCB).

In embodiments, the one or more memory dies may be wire bonded to pads on the substrate or to pads on an RDL layer on the substrate. In embodiments, conductive traces or routings within the substrate that are able to carry double data rate (DDR) signals may be used to electrically couple the one or more memory dies with the die. In embodiments, this configuration of one or more memory dies below the die may result in shorter electrical routings and faster signaling between the die and the one or more memory dies. In embodiments, the die may include a central processing unit (CPU), a graphics processor unit (GPU), or some other processor. In embodiments, the die may be a die complex, such as a system on chip (SOC).

In embodiments, one or more interconnects may extend through the molding to electrically couple one side of the package with the substrate and the die. In embodiments, the interconnects may provide power to the die. In embodiments, the interconnects may include copper pillars. In embodiments, a capacitor, for example a land side capacitor, may be coupled on the substrate below the die. In other embodiments, the capacitor may be coupled at the edge of the package and electrically coupled with the die using the one or more interconnects.

In legacy implementations, packages include a die and one or more memory dies on the same side of a substrate. As a result manufacturing difficulties are created because the memory dies are taller than the die or die complexes to which they are coupled. For example, heat spreaders that cover both the memory dies and the die require different thicknesses, which may require a pedestal-type heat sink design to accommodate the different heights. In addition, a keep out zone around the die, which may be required due to die underfill, causes the surrounding memory dies to be positioned at distances that are at least 2 mm away from the die. In addition, each of the legacy memory dies on the same side of the substrate typically require their own substrate, including interconnects such as a ball grid array (BGA), to electrically couple the legacy memory die to the substrate. This increases the overall Z-height of the package.

In embodiments described herein, the signal distances between the die and the memory dies may be reduced as compared to legacy implementations by bringing the memory dies and the die closer together. In embodiments, more compact thermal solutions for both the die and the memory dies result in an overall smaller package foot print with a higher bandwidth between the die and the memory dies. In addition, because the memory dies are able to directly couple with the substrate, overall Z-height may be reduced.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

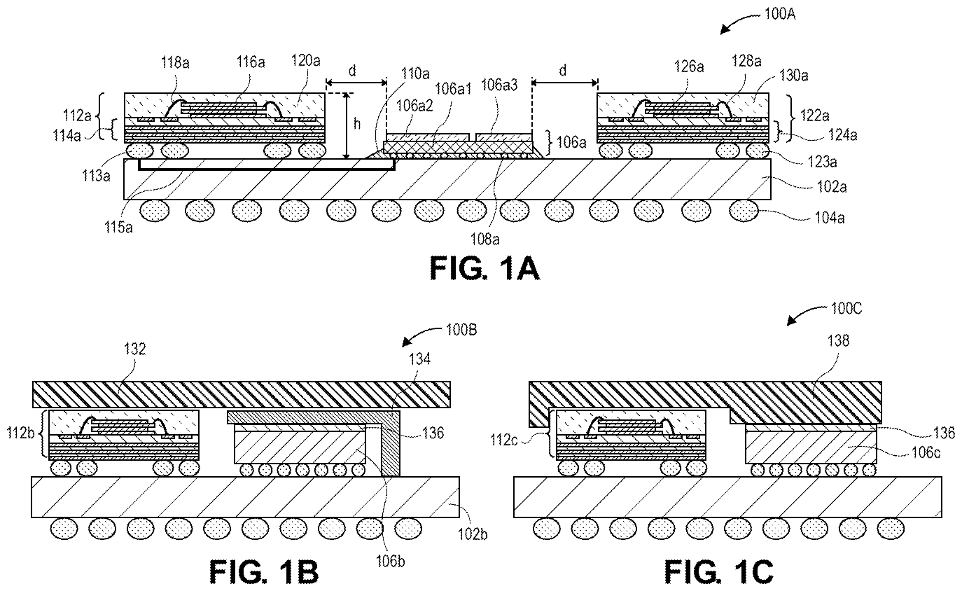

FIGS. 1A-1C illustrate cross section side views of legacy on package memory implementations. FIG. 1A illustrates a cross section side view of legacy package 100A that includes a substrate 102a, with a BGA 104a physically and electrically coupled with the substrate 102a. A die complex 106a, that may include a base die 106a1 and tiles 106a2, 106a3, may be physically and electrically coupled with a side of the substrate 102a using BGA 108a and underfill 110a. In implementations, a first memory package 112a and a second memory package 122a may be physically and electrically coupled with the side of the substrate 102a.

First memory package 112a may include a substrate 114a that is electrically and physically coupled with the substrate 102a using BGA 113a. A memory die 116a is coupled with the substrate 114a using wire bond 118a. The memory die 116a and the wire bond 118a is encapsulated within a molding 120a. Similarly, second memory package 122a may include a substrate 124a that is electrically and physically coupled with the substrate 102a using BGA 123a. A memory die 126a is coupled with the substrate 124a using wire bond 128a. The memory die 126a and the wire bond 128a is encapsulated within a mold 130a.

In this legacy implementation, the first memory package 112a and the second memory package 122a are separated from the die complex 106a by a distance d, which may be on the order of 2 mm. The separation is required due to a keep out zone that may be formed based on the underfill 110a extending beyond the edges of the die complex 106a. As a result, an electrical routing 115a that may be partially within a layer of the substrate 102a will have a length that is at least as long as a length of the first memory package 112a together with the distance d. The length of the electrical routing 115a will be a limiting factor in the bandwidth between the first memory package 112a and the die complex 106a.

In addition, the first memory package 112a and the second memory package 122a may have a height h above the side of the substrate 102a that includes the height of the substrate 114a together with a height of the molding 120a. As a result, the height h may be significantly taller than a height of the die complex 106a.

FIG. 1B shows a legacy package 100B, which may be similar to legacy package 100A of FIG. 1A. memory package 112b and die 106b may be coupled with substrate 102b, which may be similar to memory package 112a, die complex 106a, and substrate 102a of FIG. 1A. In legacy implementations, a heat spreader 132, which may be a planar heat spreader and which may be referred to as a flat heat spreader, may be thermally coupled with a top of the memory package 112b. In implementations, because a height of the memory package 112b is greater than a height of the die 106b, an integrated heat spreader 134 may be used to thermally couple the die 106b with the heat spreader 132 and with the substrate 102b. In embodiments, a thermal interface material (TIM) 136 may thermally couple the die 106b with the integrated heat spreader 134. During manufacturing, additional stages required to place the TIM 136 on the die 106b and to place the irregularly shaped integrated heat spreader 134 onto the TIM 136 and the substrate 102b increase manufacturing complexity and also increase the time required for manufacture. In addition, these additional stages may introduce defects in packages, reducing overall yield.

FIG. 1C shows package 100C, which may be similar to legacy package 100B of FIG. 1B, where a pedestal configured heat spreader 138 is used to come into thermal contact with the memory package 112c, the die 106c, and TIM 136, which may be similar to memory package 112b and die 106b of FIG. 1B. The pedestal configured heat spreader 138 introduces additional complexity into stages of the manufacturing process, requiring multiple passes or machining of the pedestal configured heat spreader 138 in order to provide an adequate thermal solution. As a result, this may add 15-20% increased cost to the heat spreader 138.

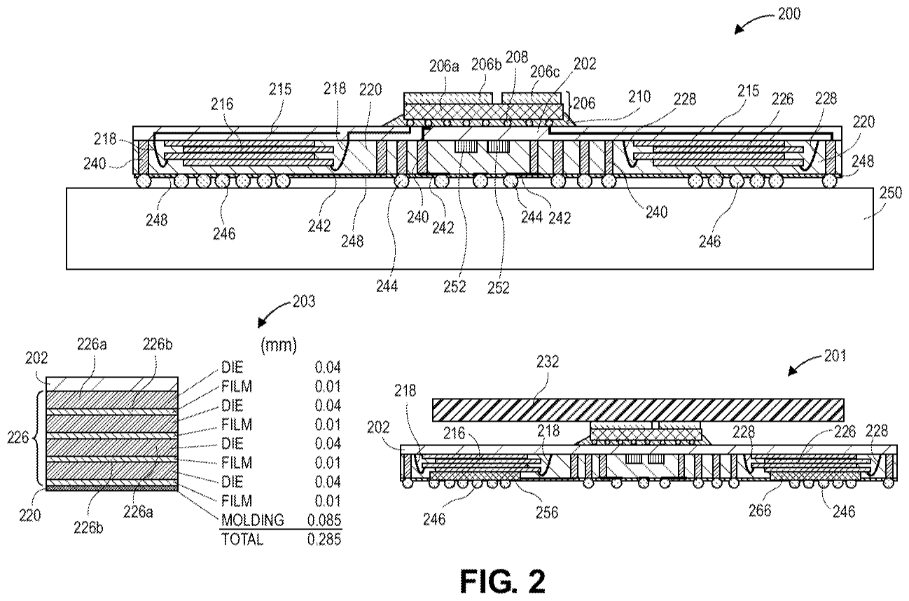

FIG. 2 illustrates cross section side views of packages that include memory dies that are beneath a top die, in accordance with various embodiments. Package 200 is a cross section side view that includes a die complex 206 that includes a base die 206a, and tiles 206b, 206c coupled with the base die 206a. In other embodiments, the die complex 206 may be a single die, or a system on chip (SOC). In embodiments, the die complex 206 may be similar to die complex 106a of FIG. 1A.

In embodiments, the die complex 206 may be electrically and physically coupled with a first side of a substrate 202 using a BGA 208 and underfill 210, which may be similar to BGA 108a and underfill 110a of FIG. 1A. In embodiments, a first memory die 216 and the second memory die 226 may be coupled with a second side of the substrate 202 on the opposite side the die complex 206. In embodiments, the first memory die 216 or the second memory die 226 may not be memory dies, and may include any type of die that may be electrically coupled with the die complex 206. In embodiments, the first memory die 216 may be electrically coupled with the substrate 202 using wire bond 218, and the second memory die 226 may be electrically coupled with the substrate 202 using wire bond 228. In embodiments, the wire bonds 218, 228 may be electrically coupled with one or more routing layers 215 within the substrate 202 in order to electrically couple the first memory die 216 and the second memory die 226 with the die complex 206.

In embodiments, a molding 220 may be formed on the second side of the substrate 202, and surround or at least partially surround the first memory die 216 and the second memory die 226. In embodiments, the molding may include a mold compound. In embodiments, one or more interconnects 240, which may include copper pillars, may extend through the molding 220 and electrically couple with the substrate 202. In embodiments, an RDL 242 may be at the bottom of the molding 220, and may electrically couple with the one or more interconnects 240. In embodiments, a solder resist layer 248, which may be a polyimide coating, may be at the bottom of the molding 220 and at least partially cover the RDL 242. In embodiments, RDL 242 may also electrically couple with one or more solder balls 244 that may be electrically and physically coupled with a PCB 250. In embodiments, the PCB 250 may be a motherboard.

In embodiments, solder balls 246 may be thermally coupled with the first memory die 216 or the second memory die 226. In embodiments, the solder balls may be some other thermally conductive substance, for example copper, which may be of any shape. In embodiments, the solder balls 246 may draw heat from the first memory die 216 or the second memory die 226 during operation down into the PCB 250. In addition, the solder balls 246 may provide additional mechanical strength to the package 200.

In embodiments, capacitors 252, which may include landside capacitors, may be coupled with the second side of the substrate 202, and proximate to the die complex 206. In embodiments, the capacitors 252 may provide power and/or to regulate power provided to the die complex 206. In embodiments, the capacitors 252 may be surrounded by the molding 220, and may be coupled with the PCB 250 using interconnects 240.

Package 201, which may be similar to package 200, shows an embodiment where a heat spreader 232, which may be similar to heat spreader 132 of FIG. 1B, is placed on top of the die complex 206. Note that in this configuration, the heat spreader 232 is planar and flat, and may extend above the first memory die 216 and the second memory die 226. In embodiments, the top side and the bottom side of the heat spreader 232 may be substantially parallel. In addition, heat slug 256 may be thermally coupled with the first memory die 216 and heat slug 266 may be thermally coupled with the second memory die 226 to facilitate the conduction of heat to the solder balls 246.

In some embodiments, the heat slugs 256 may be made of copper, such as a metal plate that includes copper, or some other thermally conductive material. In some embodiments, the heat slugs 256 may extend beneath the package and may thermally couple with features on a PCB, such as PCB 250. In some embodiments, the heat slug 256 or the heat slug 266 may be smaller than a surface of the first memory die 216 or the second memory die 226 to not interfere with wire bond 218 or with wire bond 228.

Diagram 203 shows an enlarged example of the second memory die 226 of package 200, where a portion of the substrate 202 is shown, with individual dies 226a are interleaved with film 226b, with a portion of the molding 220 at the bottom. As shown, a total thickness of the memory die 226 may range from 0.25 mm to 0.3 mm.

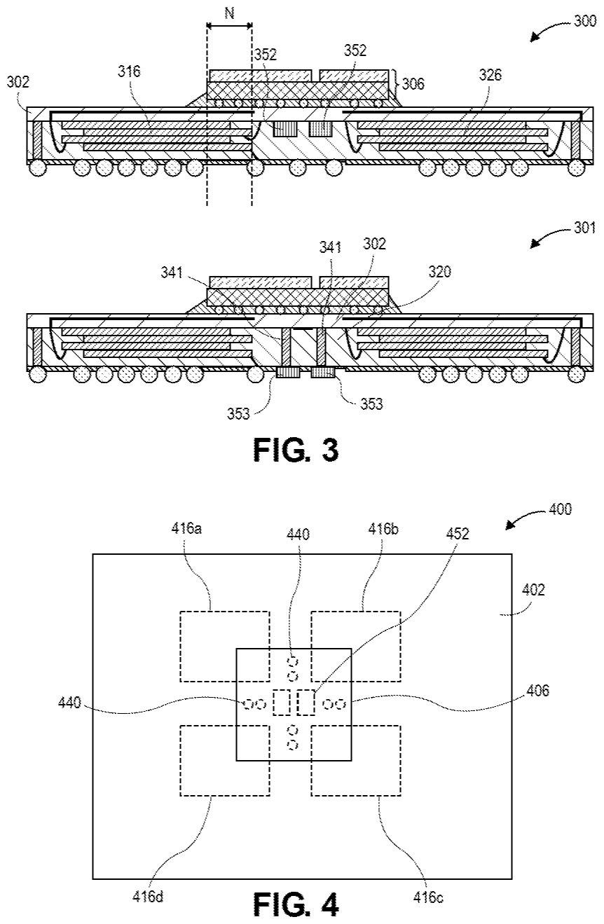

FIG. 3 illustrates cross section side views and a top-down view of memory dies that are at least partially directly below a top die, in accordance with various embodiments. Package 300, which may be similar to package 200 of FIG. 2, shows a die complex 306 that is coupled with a substrate 302, which may be similar to die complex 206 and substrate 202 of FIG. 2. A first memory die 316 and a second memory die 326, which may be similar to first memory die 216 and second memory die 226 of FIG. 2, may be electrically coupled with the substrate 302 on a side opposite the die complex 306.

In this embodiment, the first memory die 316 and the second memory die 326 may be at least partially beneath the die complex 306, relative to the substrate 302. For example, the die complex 306 may overlap the first memory die 316 by distance N. Unlike legacy implementations, this allows the first memory die 316 and the second memory die 326 to have a shorter electrical connection with the die complex 306, resulting in a higher bandwidth connection. In this embodiment, the capacitors 352 may still be physically and electrically coupled to the substrate 302, and in close proximity to the die complex 306.

Package 301, which may be similar to package 300, shows a different configuration of capacitors 353, which may be similar to capacitors 352 of package 300, where capacitors 353 are not directly coupled with the substrate 302, but instead are coupled with the substrate 302 using interconnects 341, which may be similar to interconnects 240 of FIG. 2. In embodiments, the interconnects 341 may be copper pillars that are formed within the molding 320, which may be similar to molding 220 FIG. 2.

FIG. 4 illustrates a top-down view of a package that includes multiple memory dies that are at least partially directly below a top die, in accordance with various embodiments. Package 400 shows a die complex 406 attached to a substrate 402, which may be similar to die complex 206 and substrate 202 of FIG. 2. memory dies 416a, 416b, 416c, 416d, which may be similar to first memory die 216 or similar to second memory die 226 of FIG. 2, may be below and electrically coupled with the substrate 402. In embodiments, portions of the memory dies 416a, 416b, 416c, 416d may be directly underneath the die complex 406 with respect to the plane of the substrate 402.

In embodiments, interconnects 440, which may be similar to interconnects 240 of FIG. 2, may electrically couple with the substrate 402 underneath the die complex 406 and may be electrically coupled with the die complex 406, for example, to provide power. In embodiments, the interconnects 440 may also be positioned between memory dies, for example memory die 416a and memory die 416b. In embodiments, one or more capacitors 452, which may be similar to capacitors 252 of FIG. 2, may be physically and/or electrically coupled with the substrate 402, and electrically coupled with the die complex 406. In embodiments, a molding (not shown, but may be similar to molding 220 of FIG. 2) may surround the memory dies 416a, 416b, 416c, 416d, the interconnects 440, and/or the one or more capacitors 452. In this configuration, the memory dies 416a, 416b, 416c, 416d will be physically closer to the die complex 406 than in legacy implementations, resulting in a substantially higher bandwidth for package 400.

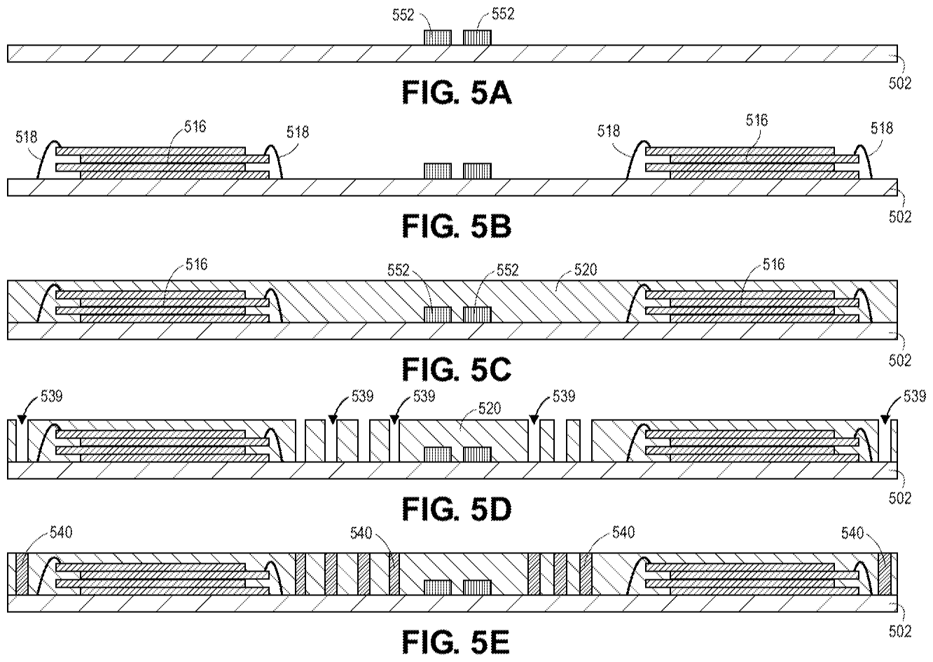

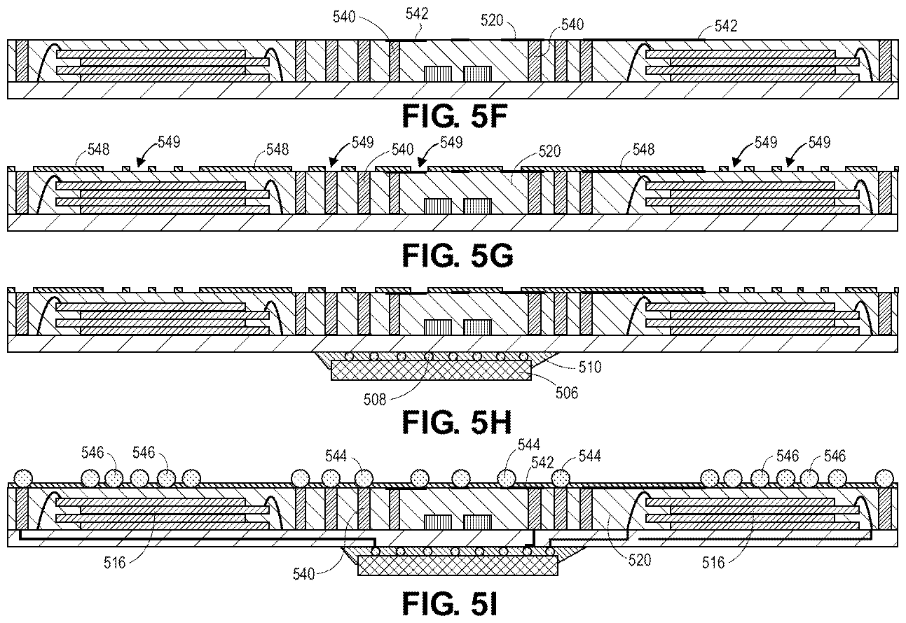

FIGS. 5A-5I illustrate cross section side views of stages in a manufacturing process for creating a package with memory dies in a molding that are beneath a top die, with a capacitor proximate to the top die, in accordance with various embodiments. FIG. 5A shows a cross section side view of a stage in the manufacturing process where a substrate 502 is provided, and one or more capacitors 552 are electrically coupled with a side of the substrate 502.

In embodiments, substrate 502 and capacitors 552 may be similar to substrate 202 and capacitors 252 of FIG. 2. In embodiments, the substrate 502 may include a plurality of layers (not shown), where each of the plurality of layers includes one or more electrical routings, which may be conductive metal routings, used to route signals and/or power around the substrate 502 and which may be electrically coupled with capacitors 552. In embodiments, the capacitors 552 may be applied using a reflow process.

FIG. 5B shows a stage in the manufacturing process where a plurality of memory dies 516, which may be similar to first memory die 216 or second memory die 226 of FIG. 2, may be physically and/or electrically coupled with the substrate 502. In embodiments, a wire bond 518, which may be similar to wire bond 218 of FIG. 2, may be used to electrically couple the memory dies 516 with the substrate 502.

FIG. 5C shows a stage in the manufacturing process where a molding 520, which may be similar to molding 220 of FIG. 2, is applied to the side of the substrate 502 and completely, or partially, surrounds the memory dies 516 and the capacitors 552. In embodiments, the molding may include a generic mold compound. In embodiments, the molding 520 may be cured using a high temperature curing process. In some embodiments, a protective film (not shown) may be applied to portions of the substrate 502 to prevent accelerated oxidation during the mold curing process. In addition, a nitrogen purse curing oven, that may include negative oxygen, may be used to reduce substrate 502 bump pad (not shown) oxidation due to contact with oxygen in the high temperature environment during the mold curing process.

FIG. 5D shows a stage in the manufacturing process where holes 539 are created into the molding 520 through to the substrate 502. In embodiments, holes 539 may be formed using laser drilling, or other techniques used to remove portions of the molding 520.

FIG. 5E shows a stage in the manufacturing process where the holes 539 of FIG. 5D are filled with an electrically conductive material to create interconnects 540, which may be similar to interconnects 240 of FIG. 2. In embodiments, the electrically conductive material may include copper that is used to create a through metal via structure. In embodiments, a plating process may be used that includes an electroless process to provide copper seed material, followed by electrolytic copper plating to fill the holes 539 of FIG. 5D with copper to create an electrically conductive interconnect 540 that electrically couples with the substrate 502.

FIG. 5F shows a stage in the manufacturing process where an RDL 542, which may be similar to RDL 242 of FIG. 2, is applied to at least a portion of the side of the molding 520. In embodiments, the RDL 542 may electrically couple with at least some of the interconnects 540, and may be used to route signal and/or power. In some embodiments, the RDL 542 may not be needed if all electrical routing is able to be performed within the substrate 502.

FIG. 5G shows a stage in the manufacturing process where a solder resist layer 548, which may be similar to solder resist layer 248 of FIG. 2, may be applied. In embodiments, the solder resist layer 548 may be a polyimide coating or some other protective or insulator coating. In embodiments, after the solder resist layer 548 is applied, various openings 549 may be created in the solder resist layer 548, for example to expose portions of the molding 520, expose interconnects 540, or to expose portions of the RDL 542. Openings 549 may be used, for example, for subsequent ball attach as described further below.

FIG. 5H shows a stage in the manufacturing process where a die complex 506, which may be similar to die complex 206 of FIG. 2, may be coupled with the surface of the substrate 502. In embodiments, the die complex 506 may be electrically coupled to the substrate 502 using BGA 508, which may be similar to BGA 208 of FIG. 2. In embodiments, an underfill 510, which may be similar to underfill 210 of FIG. 2, may be flowed underneath the die complex 506 in order to secure the die complex 506 to the substrate 502. In embodiments, the die complex 506 may be attached using thermo-compression bonding (TCB) techniques.

FIG. 5I shows a stage in the manufacturing process where solder balls 544, 546 may be applied in the openings 549 of FIG. 5G. In embodiments, the solder balls 544, which may be similar to solder balls 244 of FIG. 2, may be electrically coupled with the RDL 542 or with the interconnects 540. In embodiments, the solder balls 544 may be electrically coupled with a PCB (not shown, that may be similar to PCB 250 of FIG. 2). In embodiments, solder balls 546, which may be similar to solder balls 246 of FIG. 2, may be thermally coupled with the molding 520 proximate to the memory dies 516 to provide a thermally conductive path during operation from the memory dies 516 through the solder balls 546. In embodiments, the solder balls 544, 546 may be produced using a ball attach reflow process.

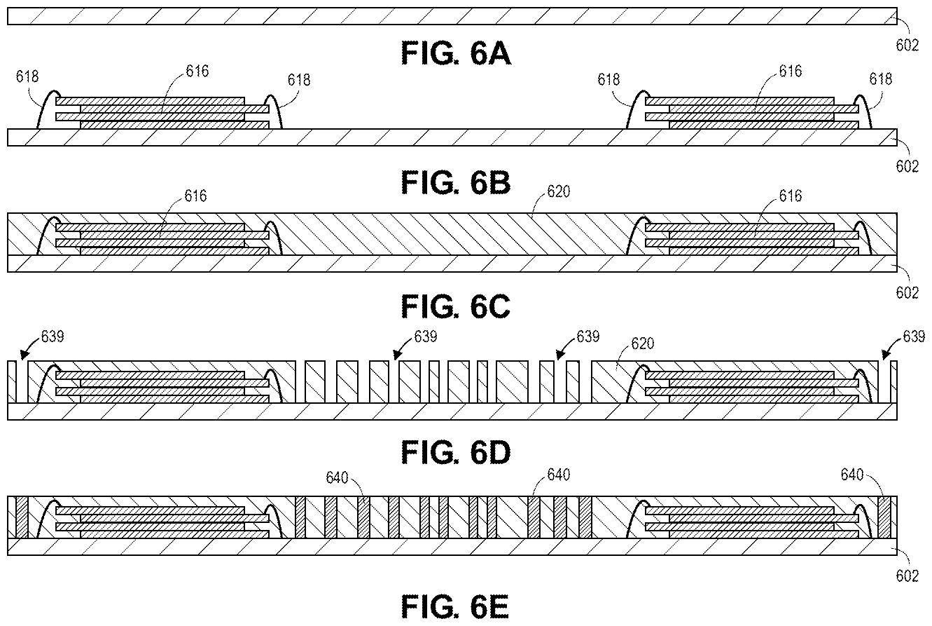

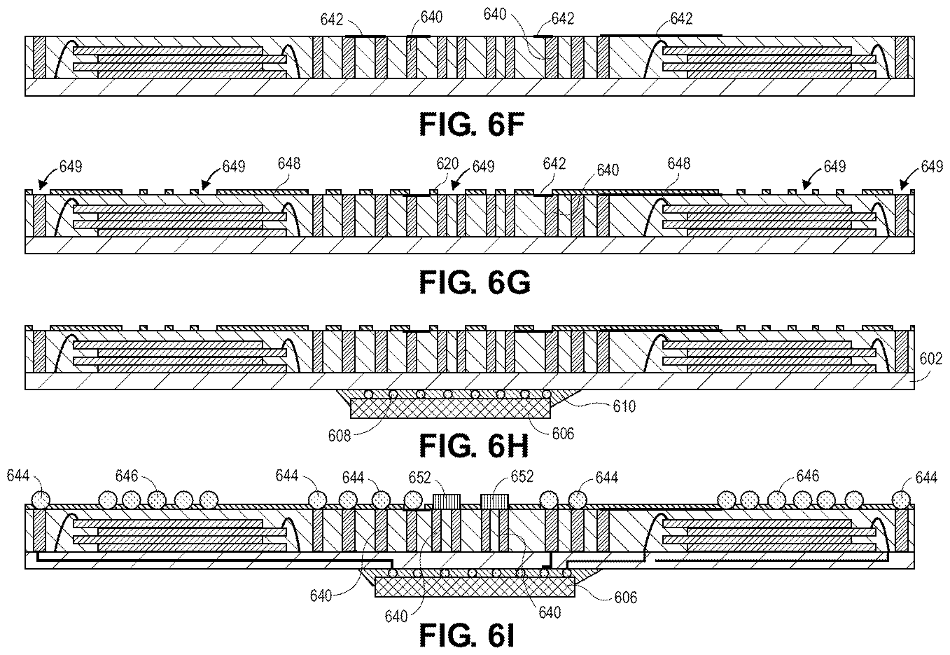

FIGS. 6A-6I illustrate cross section side views of stages in a manufacturing process for creating a package with memory dies in a molding that are beneath the top die, with a capacitor at the edge of the package where the capacitor is electrically coupled with the top die using metal vias, in accordance with various embodiments. FIG. 6A shows a cross section side view of a stage in the manufacturing process where substrate 602 is provided. In embodiments, substrate 602 may be similar to substrate 202 of FIG. 2. In embodiments, the substrate 602 may include a plurality of layers (not shown), or each of the plurality of layers includes one or more electrical routings, which may be electrically conductive metal routings, used to route signals and/or power around the substrate 602.

FIG. 6B shows a stage in the manufacturing process where a plurality of memory dies 616, which may be similar to the first memory die 216 or second memory die 226 of FIG. 2, may be physically and/or electrically coupled with the substrate 602. In embodiments, a wire bond 618, which may be similar to wire bond 218 of FIG. 2, may be used to electrically couple the memory die 616 with the substrate 602.

FIG. 6C shows a stage in the manufacturing process where a molding 620, which may be similar to molding 220 of FIG. 2 or similar to molding 520 of FIG. 5C, is applied to the side of the substrate 602 and completely, or partially, surrounds the memory dies 616. In embodiments, the molding 620 may be cured using a high-temperature curing process. In embodiments, a protective film (not shown) may be applied to portions of the substrate 602 to prevent accelerated oxidation during the mold curing process. In addition, a nitrogen purse curing oven, that may include negative oxygen, may be used to reduce substrate 602 bump oxidation due to contact with oxygen in the high temperature environment during the mold curing process.

FIG. 6D shows a stage in the manufacturing process where holes 639, which may be similar to holes 539 of FIG. 5D, are formed into the molding 620 through to the substrate 602. In embodiments, holes 639 may be formed using laser drilling, or other techniques to remove portions of the molding 620.

FIG. 6E shows a stage in the manufacturing process where the holes 639 of FIG. 6D are filled with an electrically conductive material to create interconnects 640, which may be similar to interconnects 240 of FIG. 2. In embodiments, the electrically conductive material may include copper to create a through metal via structure. In embodiments, a plating process may be used that includes an electroless process to provide copper seed material, followed by electrolytic copper plating to fill the holes 639 of FIG. 6D with copper to create electrically conductive interconnect 640 that may electrically couple with the substrate 602.

FIG. 6F shows a stage in the manufacturing process where an RDL 642, which may be similar to RDL 242 of FIG. 2 or RDL 542 of FIG. 5F, is applied to at least a portion of the side of the molding 620. In embodiments, the RDL 642 may electrically couple with at least some of the interconnects 640 to route signal and/or power. In embodiments, the RDL 642 may not be needed if all electrical routing is able to be performed within the substrate 602.

FIG. 6G shows a stage in the manufacturing process where a solder resist layer 648, which may be similar to solder resist layer 248 of FIG. 2, or may be similar to solder resist layer 548 of FIG. 5G, may be applied. In embodiments, the solder resist layer 648 may be a polyimide coating or some other protective or insulator coating. In embodiments, after the solder resist layer 648 is applied, various openings 649 may be created in the solder resist layer 648, for example to expose portions of the molding 620, expose interconnects 640, or to expose portions of the RDL 642. Openings 649 may be used, for example, for subsequent ball attach or capacitor attach as described further below.

FIG. 6H shows a stage in the manufacturing process where a die complex 606, which may be similar to die complex 206 of FIG. 2, or die complex 506 of FIG. 5H, may be electrically coupled to the substrate 602 using BGA 608, which may be similar to BGA 208 of FIG. 2. In embodiments, an underfill 610, which may be similar to underfill 210 of FIG. 2, may be flowed underneath a die complex 606 in order to secure the die complex 606 to the substrate 602. In embodiments, the die complex 606 may be attached using a TCB technique.

FIG. 6I shows a stage in the manufacturing process where solder balls 644, 646, and capacitors 652, which may be similar to capacitors 252 of FIG. 2, may be applied in the openings 649 of FIG. 6G. In embodiments, the solder balls 644 may be similar to solder balls 244 of FIG. 2. In embodiments, solder balls 646, which may be similar to solder balls 246 of FIG. 2, may be thermally coupled with the molding 620 proximate to the memory die 616 to provide a thermally conductive path during operation from the memory die 616 through the solder balls 646. In addition, the solder balls 646 also provide additional mechanical stability.

In embodiments, capacitors 652 may be applied in the openings 649 of FIG. 6G and may be electrically coupled with one or more interconnects 640 that in turn may be electrically coupled with the die complex 606. This way, capacitors 652 may provide power and/or regulate power to the die complex 606 while not being directly physically connected to the substrate 602. In embodiments, the capacitor 652, and the solder balls 644, 646 may be physically and/or electrically coupled with a PCB (not shown, but may be similar to PCB 250 of FIG. 2). In embodiments, the solder balls 644, 646 and capacitors 652 may be applied using a reflow process.

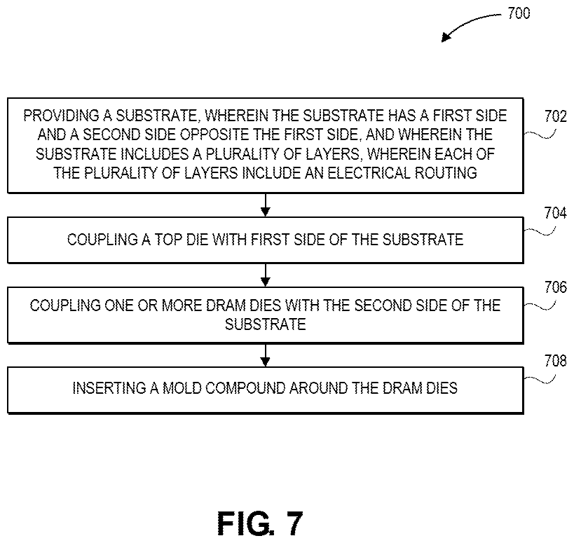

FIG. 7 illustrates an example of a process for creating a package that includes one or more memory dies in a molding that are beneath a top die, in accordance with various embodiments. Process 700 may be performed using the systems, apparatus, tools, techniques, and/or processes that are described herein, and particularly with respect to FIGS. 1A-6I.

At block 702, the process may include providing a substrate, wherein the substrate has a first side and a second side opposite the first side, and wherein the substrate includes a plurality of layers, wherein each of the plurality of layers include an electrical routing. In embodiments, the substrate may be similar to substrate 202 of FIG. 2, substrate 302 of FIG. 3, substrate 402 of FIG. 4, substrate 502 of FIGS. 5A-5I, or substrate 602 of FIGS. 6A-6I. In embodiments, the electrical routing within the plurality of layers may be similar to one or more routing layers 215 of FIG. 2.

At block 704, the process may further include coupling a top die with first side of the substrate. In embodiments, the top die may be similar to die complex 206 which may include base die 206a and tiles 206b, 206c of FIG. 2, die complex 306 of FIG. 3, die complex 406 of FIG. 4, die complex 506 of FIGS. 5H-5I, or die complex 606 of FIGS. 6H-6I.

At block 706, the process may further include coupling one or more memory dies with the second side of the substrate. In embodiments, the one or more memory dies may be similar to memory dies 216, 226 of FIG. 2, memory dies 316, 326 of FIG. 3, memory dies 416a, 416b, 416c, 416d of FIG. 4, memory dies 516 of FIG. 5B, or memory dies 616 of FIG. 6B.

At block 708, the process may further include inserting a mold compound around the memory dies. In embodiments, the mold compound may be similar to molding 220 of FIG. 2, molding 320 of FIG. 3, molding 520 of FIG. 5C, or molding 620 of FIG. 6C.

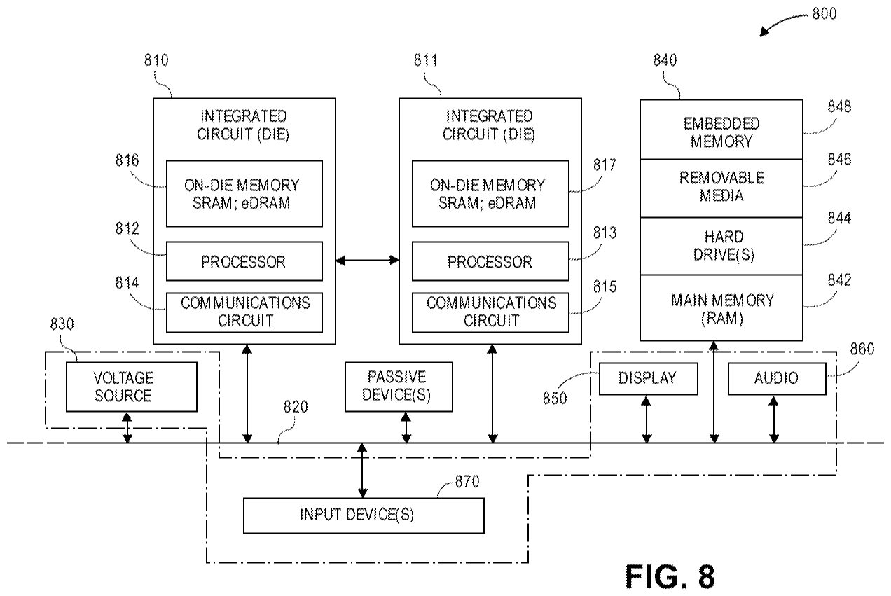

FIG. 8 is a schematic of a computer system 800, in accordance with an embodiment of the present invention. The computer system 800 (also referred to as the electronic system 800) as depicted can embody memory in a molding beneath a die in a package substrate, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, memory in a molding beneath a die in a package substrate, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (ememory).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as ememory.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having memory in a molding beneath a die in a package substrate, according to any of the several disclosed embodiments and their equivalents, an electronic system, a computer system, one or more methods of fabricating an integrated circuit, and one or more methods of fabricating an electronic assembly that includes a package substrate having memory in a molding beneath a die in a package substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having memory in a molding beneath a die in a package substrate embodiments and their equivalents. A foundation substrate may be included, as represented by the dashed line of FIG. 8. Passive devices may also be included, as is also depicted in FIG. 8.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

The following paragraphs describe examples of various embodiments.

Example 1 is a package comprising: a substrate with a first side and a second side opposite the first side, wherein the substrate includes a redistribution layer; a die on the first side of the substrate, wherein the die is electrically coupled with the redistribution layer; and a memory die on the second side of the substrate, wherein the memory die is electrically coupled with the redistribution layer using a wire bond, and wherein the memory die is electrically coupled with the die.

Example 2 includes the package of example 1, further comprising a molding surrounding the memory die, wherein the molding is physically coupled with the second side of the substrate.

Example 3 includes the package of example 2, further comprising an interconnect in the molding, wherein the interconnect is electrically coupled with the redistribution layer and is electrically coupled with the die.

Example 4 includes the package of example 3, wherein the interconnect includes a metal via.

Example 5 includes the package of examples 3 or 4, wherein the interconnect is coupled with a capacitor.

Example 6 includes the package of examples 1, 2, 3, 4, or 5, wherein a portion of the memory die is beneath a portion of the die with respect to a surface of the substrate.

Example 7 includes the package of examples 1, 2, 3, 4, 5, or 6, wherein the memory die is a selected one of a dynamic random access memory die, or a static random access memory die.

Example 8 includes the package of examples 1, 2, 3, 4, 5, 6, or 7, wherein the memory die is a first memory die, and wherein the wire bond is a first wire bond; and further comprising a second memory die on the second side of the substrate, wherein the second memory die is electrically coupled with the redistribution layer using a second wire bond, and wherein the second memory die is electrically coupled with the die.

Example 9 includes the package of example 8, further comprising a molding surrounding the first memory die and the second memory die, wherein the molding is physically coupled with the second side of the substrate.

Example 10 includes the package of example 9, wherein the molding includes an epoxy resin.

Example 11 includes the package of examples 1, 2, 3, 4, 5, 6, 7, 8, 9, or 10, wherein the die includes a plurality of dies.

Example 12 is a package comprising: a substrate having a first side and a second side opposite the first side, wherein the substrate includes a plurality of layers, wherein at least some of the plurality of layers include an electrical routing; a top die physically and electrically coupled with the first side of the substrate; a plurality of memory dies physically and electrically coupled with the second side of the substrate, wherein the plurality of memory dies are electrically coupled with the top die through the substrate; and wherein the plurality of memory dies are at least partially surrounded by a molding.

Example 13 includes the package of example 12, wherein the top die includes a selected one or more of: a system on chip, a graphics processor unit or a central processing unit.

Example 14 includes the package of examples 12 or 13, wherein at least a portion of at least one of the plurality of memory dies is underneath the top die with respect to the first side of the substrate.

Example 15 includes the package of examples 12, 13, or 14, wherein the plurality of memory dies have a first side and a second side opposite the first side, wherein the first side of the memory dies are coupled with the second side of the substrate.

Example 16 includes the package of example 15, wherein the second side of one of the memory dies is thermally coupled with a thermally conductive material, wherein the thermally conductive material includes a selected one or more of: solder balls or a metal plate that includes copper.

Example 17 includes the package of examples 12, 13, 14, 15, or 16, wherein at least some of the plurality of memory dies are electrically coupled with the electrical routing of the at least some of the plurality of layers of the substrate.

Example 18 includes the package of example 17, wherein at least some of the plurality of memory dies are electrically coupled with the electrical routing using a wire bond.

Example 19 includes the package of examples 12, 13, 14, 15, 16, 17, or 18, further comprising: a printed circuit board (PCB); and wherein the package is physically and electrically coupled with the PCB.

Example 20 includes the package of examples 12, 13, 14, 15, 16, 17, 18, or 19, further comprising: a heat spreader on top of the top die, wherein the heat spreader has a first side and a second side opposite the first side, wherein the first side and the second side are substantially planar, and wherein the first side and the second side are substantially parallel; and wherein the heat spreader is above at least a portion of the at least one of the plurality of memory dies with respect to the first side of the substrate.

Example 21 is a method for creating a package, the method comprising: providing a substrate, wherein the substrate has a first side and a second side opposite the first side, and wherein the substrate includes a plurality of layers, wherein each of the plurality of layers include an electrical routing; coupling a top die with first side of the substrate; coupling one or more memory dies with the second side of the substrate; and inserting a mold compound around the memory dies.

Example 22 includes the method of example 21, further comprising thermally coupling one or more solder balls to the one or more memory dies.

Example 23 includes the method of examples 21 or 22, wherein at least one of the one or more memory dies are beneath the top die with respect to the first side of the substrate.

Example 24 includes the method of examples 21, 22, or 23, wherein coupling the top die with the first side of the substrate further includes electrically coupling the top die with the substrate, wherein coupling the one or more memory dies with the second side of the substrate further includes electrically coupling the one or more memory dies with the substrate, and wherein the one or more memory dies and the top die are electrically coupled with each other.

Example 25 includes the method of examples 21, 22, 23, or 24, further comprising coupling one or more capacitors with the second side of the substrate, wherein the one or more capacitors are electrically coupled with the top die.

What is claimed is:

1. A package comprising:
a substrate with a first side and a second side opposite the first side, wherein the substrate includes a redistribution layer;
a die on the first side of the substrate, wherein the die is electrically coupled with the redistribution layer; and
a memory die on the second side of the substrate, wherein the memory die is electrically coupled with the redistribution layer using a wire bond, and wherein the memory die is electrically coupled with the die.

2. The package of claim 1, further comprising a molding surrounding the memory die, wherein the molding is physically coupled with the second side of the substrate.

3. The package of claim 2, further comprising an interconnect in the molding, wherein the interconnect is electrically coupled with the redistribution layer and is electrically coupled with the die.

4. The package of claim 3, wherein the interconnect includes a metal via.

5. The package of claim 3, wherein the interconnect is coupled with a capacitor.

6. The package of claim 1, wherein a portion of the memory die is beneath a portion of the die with respect to a surface of the substrate.

7. The package of claim 1, wherein the memory die is a selected one of a dynamic random access memory die, or a static random access memory die.

8. The package of claim 1, wherein the memory die is a first memory die, and wherein the wire bond is a first wire bond; and further comprising a second memory die on the second side of the substrate, wherein the second memory die is electrically coupled with the redistribution layer using a second wire bond, and wherein the second memory die is electrically coupled with the die.

9. The package of claim 8, further comprising a molding surrounding the first memory die and the second memory die, wherein the molding is physically coupled with the second side of the substrate.

10. The package of claim 9, wherein the molding includes an epoxy resin.

11. The package of claim 1, wherein the die includes a plurality of dies.

12. A package comprising:
a substrate having a first side and a second side opposite the first side, wherein the substrate includes a plurality of layers, wherein at least some of the plurality of layers include an electrical routing;
a top die physically and electrically coupled with the first side of the substrate;
a plurality of memory dies physically and electrically coupled with the second side of the substrate, wherein the plurality of memory dies are electrically coupled with the top die through the substrate; and
wherein the plurality of memory dies are at least partially surrounded by a molding.

13. The package of claim 12, wherein the top die includes a selected one or more of: a system on chip, a graphics processor unit or a central processing unit.

14. The package of claim 12, wherein at least a portion of at least one of the plurality of memory dies is underneath the top die with respect to the first side of the substrate.

15. The package of claim 12, wherein the plurality of memory dies have a first side and a second side opposite the first side, wherein the first side of the memory dies are coupled with the second side of the substrate.

16. The package of claim 15, wherein the second side of one of the memory dies is thermally coupled with a thermally conductive material, wherein the thermally conductive material includes a selected one or more of: solder balls or a metal plate that includes copper.

17. The package of claim 12, wherein at least some of the plurality of memory dies are electrically coupled with the electrical routing of the at least some of the plurality of layers of the substrate.

18. The package of claim 17, wherein at least some of the plurality of memory dies are electrically coupled with the electrical routing using a wire bond.

19. The package of claim 12, further comprising:
a printed circuit board (PCB); and
wherein the package is physically and electrically coupled with the PCB.

20. The package of claim 12, further comprising:
a heat spreader on top of the top die, wherein the heat spreader has a first side and a second side opposite the first side, wherein the first side and the second side are substantially planar, and wherein the first side and the second side are substantially parallel; and
wherein the heat spreader is above at least a portion of the at least one of the plurality of memory dies with respect to the first side of the substrate.

21. A method for creating a package, the method comprising:
providing a substrate, wherein the substrate has a first side and a second side opposite the first side, and wherein the substrate includes a plurality of layers, wherein each of the plurality of layers include an electrical routing;
coupling a top die with first side of the substrate;
coupling one or more memory dies with the second side of the substrate; and
inserting a mold compound around the memory dies.

22. The method of claim 21, further comprising thermally coupling one or more solder balls to the one or more memory dies.

23. The method of claim 21, wherein at least one of the one or more memory dies are beneath the top die with respect to the first side of the substrate.

24. The method of claim 21, wherein coupling the top die with the first side of the substrate further includes electrically coupling the top die with the substrate, wherein coupling the one or more memory dies with the second side of the substrate further includes electrically coupling the one or more memory dies with the substrate, and wherein the one or more memory dies and the top die are electrically coupled with each other.

25. The method of claim 21, further comprising coupling one or more capacitors with the second side of the substrate, wherein the one or more capacitors are electrically coupled with the top die.
